(19) United States
(12) Patent Application Publication
(10) Pub. No.: US 2002/0130352 A1
(43) Pub. Date: Sep. 19, 2002

(54) Semiconductor device comprising an EEPROM memory and a FLASH-EPROM memory, and method of manufacturing such a semiconductor device

(76) Inventors: Guido Jozef Maria Dormans, Nijmegen (NL); Johannes Dijkstra, Nijmegen (NL); Robertus Dominicus Joseph Verhaar, Nijmegen (NL)

Correspondence Address: Corporate Patent Counsel, U.S. Philips Corporation, 580 White Plains Road, Tarrytown, NY, 10591, US

(21) Appl. No.: 10/022,378

(22) Filed: Dec. 13, 2001

(30) Foreign Application Priority Data
Dec. 22, 2000 (EP) 00204785.0

(51) Int. Cl. H01L 29/788

(52) U.S. Cl. 257/315

(57) ABSTRACT

A semiconductor device comprising an EEPROM and a FLASH-EPROM memory is described. The EEPROM memory comprises a matrix of memory cells (ME) with a selection transistor (T2) having a selection gate (3) and arranged in series with a memory transistor (T1) having a floating gate (1) and a control gate (2). The selection transistor is also connected to a bit line (BL) and the memory transistor is also connected to a common source line (SO) of the EEPROM memory. The FLASH-EPROM memory comprises a matrix of memory cells (MF) with a memory transistor (T3) having a floating gate (4) and a control gate (5). The memory cells of the FLASH-EPROM memory also comprise a transistor (T4) having a control gate (6) connected in series with the memory cell. The memory transistor is also connected to a bit line, and the transistor, which is connected in series with the memory transistor, is also connected to a common source line (SO) of the FLASH-EPROM memory. Similarly as the memory cells of the EEPROM memory, the memory cells of the FLASH-EPROM memory can be programmed by using Fowler-Nordheim tunneling. Consequently, the semiconductor device is suitable for use in low-voltage and low-power applications, i.e. the device can be used in contactless smart cards.

The invention relates to a semiconductor device comprising an EEPROM and a FLASH-EPROM memory, in which the EEPROM memory comprises a matrix of rows and columns of memory cells with a selection transistor having a selection gate and, arranged in series therewith, a memory transistor having a floating gate and a control gate, in which the selection transistor is further connected to a bit line of the EEPROM memory and the memory transistor is connected to a source line of the EEPROM memory, which source line is common for a plurality of memory cells, and in which the FLASH-EPROM memory comprises a matrix of rows and columns of memory cells with a memory transistor having a floating gate and a control gate. The invention also relates to a method of manufacturing such a semiconductor device.

EEPROM memories are particularly suitable for storing data which must be changed repeatedly. The data may be changed frequently, more than a million times, in every memory cell without influencing the data in neighboring memory cells. Data stored in such memories are also retained for a long time. The entry and erasure of data proceeds by Fowler-Nordheim tunneling, so that entry and erasure of data requires a relatively small amount of electric power.

The memory cells of FLASH-EPROM memories may be realized on a much smaller part of a surface of a semiconductor body than the memory cells of EEPROM memories: in practice, on less than 30% of the surface. However, in memory cells of such memories, the data cannot be changed so often without influencing the data in neighboring memory cells. FLASH-EPROM memories are suitable for storing data which do not need to be changed frequently such as, for example, codes such as passwords or computer programs.

Particularly for those applications in which a relatively large number of code and program data and a relatively small number of data to be frequently changed must be stored, it is of great advantage to combine both memories in one semiconductor device. In addition to said memories, such a semiconductor device comprises electric circuits for programming, erasing and reading the memories, a microprocessor for processing the data and circuits for entering and exiting data.

U.S. Pat. No. 5,850,092 discloses a semiconductor device of the type described in the opening paragraph, in which the memory cells of the EEPROM memory are constituted by a selection transistor and, arranged in series therewith, a memory transistor having a floating gate and a control gate, and in which the memory cells of the FLASH-EPROM memory are constituted by a memory transistor in the form of a MOS transistor having a floating gate and a control gate.

Data can be entered into and erased from the memory cells of the EEPROM memory by means of Fowler-Nordheim tunneling. Data are entered into the memory cells of the FLASH-EPROM memory by injecting “hot electrons” into the floating gate from the semiconductor region underneath the floating gate. The data are erased again by depleting the injected electrons by means of Fowler-Nordheim tunneling to the semiconductor region underneath the floating gate. For programming the memory cells in this way, an electric power is required which is much larger than the power required for entering data into the memory cells of the above-mentioned EEPROM memory.

It is an object of the invention to provide a semiconductor device of the type described in the opening paragraph, in which the entry of data into the FLASH-EPROM memory does not require more electric power than the entry of data into the EEPROM memory. The semiconductor device according to the invention is particularly suitable for use in contactless smart cards. In practice, such smart cards are provided with a coil; data are entered inductively. The required electric voltages are also presented inductively. In these types of smart cards, it is of great importance that the semiconductor device incorporated in these cards uses little energy during operation. This semiconductor device in these smart cards can then be programmed in such a way that the card is suitable as a credit card, an ID card, a bank pass, or telephone card, etc.

According to the invention, the semiconductor device described in the opening paragraph is therefore characterized in that, in addition to the memory transistor having a floating gate and a control gate, the memory cells of the FLASH-EPROM memory comprise a transistor arranged in series with this memory transistor and having a control gate, the memory transistor being further connected to a bit line of the FLASH-EPROM memory, and the transistor arranged in series with the memory transistor being connected to a source line of the FLASH-EPROM memory, which source line is common for a large number of memory cells.

The entry of data into the memory cells of this FLASH-EPROM memory may be realized similarly as the entry of data into the memory cells of the EEPROM memory by means of Fowler-Nordheim tunneling. As regards energy consumption, a semiconductor device with this combination of EEPROM and FLASH-EPROM memory is eminently suitable for use in contactless smart cards.

The memory cells of the FLASH-EPROM memory may also be made in a very small size. The reason is the use of the circuit of the memory transistor and the transistor arranged in series therewith. When programming and erasing memory cells, a large positive voltage and a large negative voltage, respectively, are applied to the control gate of the memory transistors. No voltages are applied to the transistor arranged in series with the memory transistor; 0 volt at the control gate and the source. Also when the data stored in the memory cells are being read, the voltages applied to the series-arranged transistor are always small. This transistor may be very small and may be made with a very thin gate oxide. In practice, less than 30% space is required for manufacturing a total memory cell, as compared with the manufacture of a memory cell of an EEPROM memory.

In practice, said memories are organized in such a way that a plurality of memory cells, for example, a plurality of memory cells arranged in a column of the matrix is erased simultaneously. To this end, the control gates of these memory transistors are interconnected so that a high erase voltage can be applied simultaneously to these control gates. For example, eight memory transistors may be connected so that the data can be erased per byte. A much larger number of memory transistors may also be connected in this way.

When programming a memory cell of the FLASH-EPROM memory, a high positive voltage is applied to the control gate of the memory transistor, so that the transistor acquires a threshold voltage of, for example, +3 V. This high positive voltage is thus also applied to the control gates of neighboring memory transistors arranged in the same column. To prevent these neighboring transistors from being programmed as well, a positive voltage of, for example, 5 V is applied to the bit lines connected to the drain of these transistors. This voltage then also reaches the drains of other memory transistors connected to these bit lines and arranged in rows of the matrix. When this is often the case and when the last-mentioned transistors are programmed, the threshold voltage of these transistors may change so that data can be read in a less reliable way. This limits the number of times the data in a memory cell of this memory can be changed without detrimentally influencing the contents of other memory cells. This phenomenon does not occur in the EEPROM memory because the drains of memory transistors in this memory are not connected to bit lines but to the common source line to which no voltage is applied during operation.

Similarly as the known semiconductor device described, the semiconductor device according to the invention comprises a silicon body having a surface which is provided at the area of the memory cells of the EEPROM memory with a layer of silicon oxide having a thickness which renders it suitable as a gate oxide for the selection transistor, which layer underneath the floating gate of the memory transistor is provided with a part having a smaller thickness which renders said part of the layer of silicon oxide suitable as a tunnel oxide for the memory transistor.

In the semiconductor device according to the invention, the surface of the silicon body is provided with a layer of silicon oxide at the area of the memory cells of the FLASH-EPROM memory underneath the control gates of the transistors arranged in series with the memory transistors, which layer of silicon oxide has a thickness which is equal to the thickness of the part having the smaller thickness and being present underneath the floating gate of the memory transistors of the EEPROM memory. When manufacturing this device, both the tunnel oxide of the memory transistor of the EEPROM memory and the gate oxide of the EEPROM memory and the gate oxide of the transistor arranged in series with the memory transistor of the FLASH-EPROM memory can be formed with one layer of silicon oxide in one and the same process step. This layer is relatively thin. A gate oxide having such a small thickness may be used because use is made of the above-mentioned special circuit in the semiconductor device.

In the known semiconductor device described, the layer of gate oxide of the selection transistor in the memory cells of the EEPROM memory has a thickness of between 15 and 25 nm, and the layer of tunnel oxide has a thickness of between 7 and 9 nm. In the memory cells of the FLASH-EPROM memory, the layer of silicon oxide underneath the floating gates of the memory transistors has a thickness of between 9 and 12 nm. The application of these silicon oxide layers with three different thicknesses renders the manufacture of the known semiconductor device complicated and expensive.

In the semiconductor device according to the invention, the surface of the silicon body is further provided with a layer of silicon oxide, preferably at the area of the memory cells of the FLASH-EPROM memory underneath the floating gates of the memory transistors, which layer of silicon oxide has a thickness which is also equal to the thickness of the part having the smaller thickness and being present underneath the floating gate of the memory transistors of the EEPROM memory. Only two layers of silicon oxide with a different thickness are necessary for manufacturing the EEPROM memory and the FLASH-EPROM memory.

The invention also relates to a method of manufacturing the last mentioned embodiment of the semiconductor device. According to the invention, this method is characterized in that, after active semiconductor regions of a first conductivity type adjacent the surface of the silicon body have been formed in said silicon body at the area of memory cells to be formed in the two memories, the silicon body is subjected to a first oxidation process in which the surface of the silicon body is provided with a first layer of silicon oxide in which windows are formed at the area of floating gates to be formed in the memory transistors of the EEPROM memory and at the area of the memory cells to be formed in the FLASH-EPROM memory, whereafter the silicon body is subjected to a second oxidation process in which a second layer of silicon oxide is formed within the windows with such a thickness that this layer can serve as a tunnel oxide for the memory transistors to be formed in the two memories and as a gate oxide of the transistor arranged in series with the memory transistor of the FLASH-EPROM memory, and in which the first layer of silicon oxide acquires such a larger thickness that it can serve as a gate oxide for the selection transistors to be formed in the EEPROM memory. The tunnel oxide and the gate oxide required in the memory cells of both memories may be realized in a simple manner. In one process step, windows can be formed at the area of the floating gates of the memory transistors to be formed in the EEPROM memory and at the area of the memory cells of the FLASH-EPROM memory to be formed. Only two oxidation treatments are required.

It is to be noted that the realization of the known semiconductor device described above is much more complicated. In this device, three oxidation treatments are necessary for forming the required gate and tunnel oxides and two treatments are required for forming the gate and tunnel oxides for the memory cells of the EEPROM memory, and one treatment is required for forming the tunnel oxide of the memory cells of the FLASH-EPROM memory. During the first two oxidation treatments, the active regions for the memory cells to be formed in the FLASH-EPROM memory must be masked, while the active regions for the memory cells to be formed in the EEPROM memory must be masked during the third oxidation treatment.

To program and erase the memory cells of the EEPROM memory more easily, the active regions for the memory cells of the EEPROM memory are preferably provided, prior to the first oxidation treatment, with semiconductor regions of the second conductivity type and adjacent the surface at the area of the floating gates to be formed in the memory transistors.

The method is further simplified when after the formation of the two layers of silicon oxide, a first layer of amorphous or polycrystalline silicon is deposited in which both the floating gates of the memory transistors and the selection gates of the selection transistors of the memory cells of the EEPROM memory, and the floating gates of the memory transistors and the control gates of the FLASH-EPROM memory transistors arranged in series therewith are formed.

Moreover, it is advantageous to provide the floating gates with a layer of dielectric after the formation of these gates of the memory cells of both memories in the first layer of amorphous or polycrystalline silicon, whereafter a second layer of amorphous or polycrystalline silicon is deposited, in which layer the control gates of the memory transistors of the memory cells of the EEPROM memory and the control gates of the memory transistors of the memory cells of the FLASH-EPROM memory are formed.

These and other aspects of the invention are apparent from and will be elucidated with reference to the embodiments described hereinafter.

In the drawings:

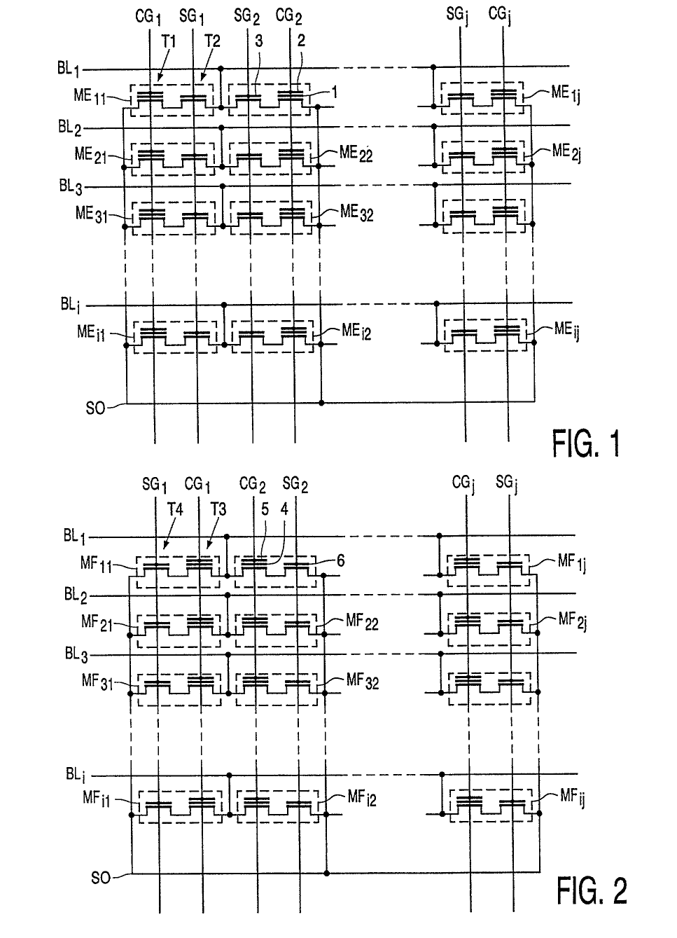

FIG. 1 is an electric circuit diagram of an EEPROM memory as used in the semiconductor device according to the invention,

FIG. 2 is an electric circuit diagram of a FLASH-EPROM memory as used in the semiconductor device according to the invention,

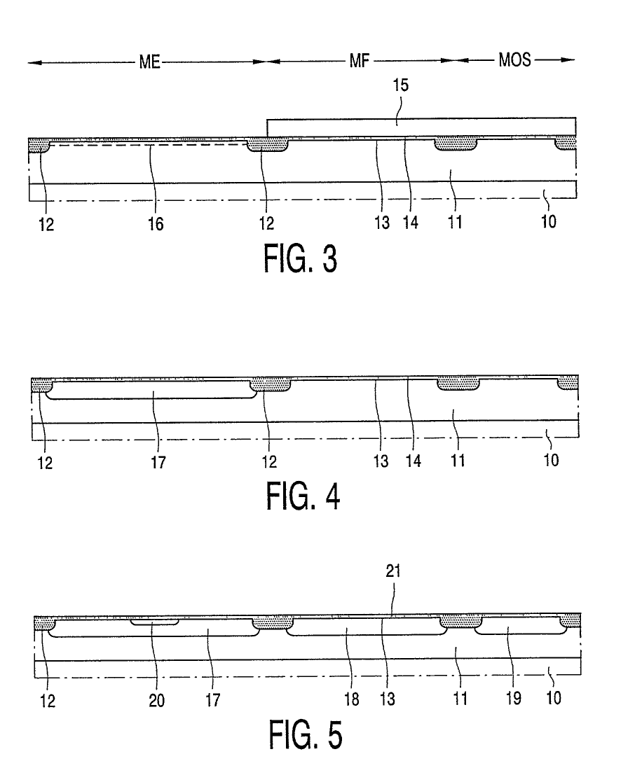

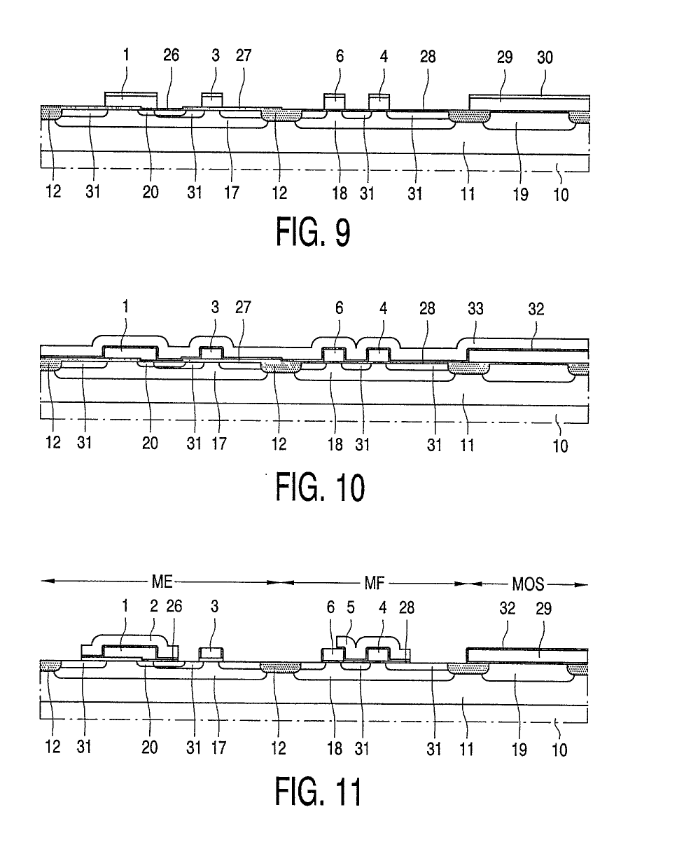

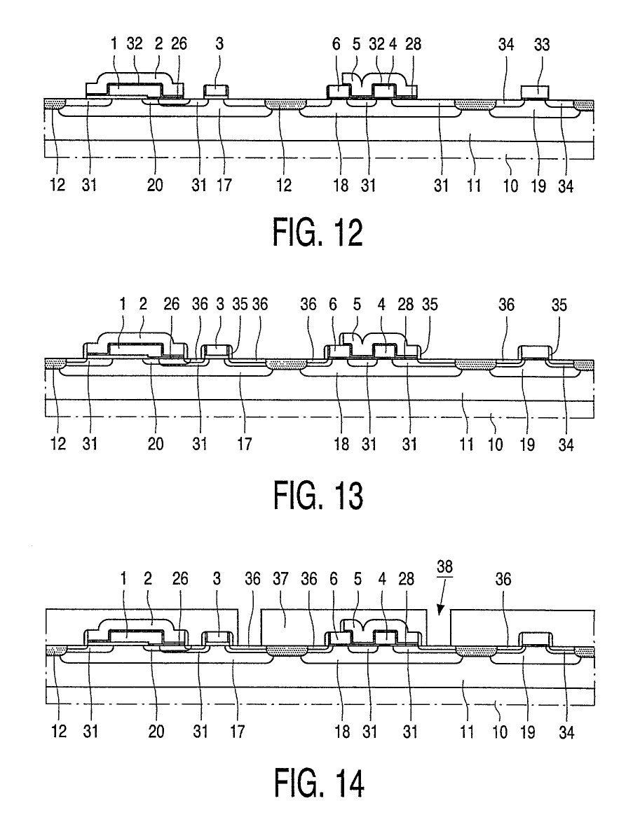

FIGS. 3 to 14 show diagrammatically and in cross-sections several stages of manufacturing the semiconductor device.

FIGS. 1 and 2 are electric circuit diagrams of relevant parts of an EEPROM memory and a FLASH-EPROM memory, respectively, as used in the semiconductor device according to the invention.

The EEPROM memory shown in FIG. 1 comprises a matrix of memory cells MEᵢⱼ arranged in rows and columns, in which i is the number in the row and j is the number in the column. Each memory cell comprises a memory transistor T1 having a floating gate 1 and a control gate 2 and, arranged in series therewith, a selection transistor T2 having a selection gate 3. The control gates 1 of a plurality of memory transistors T1, for example, eight or more transistors, are interconnected per column by lines CGⱼ, while the selection gates 3 of the selection transistors T2 are interconnected per column by lines SGⱼ. The selection transistors T2 are also interconnected per row by bit lines BLᵢ, and the memory transistors T1 are also interconnected by a source line SO which is common for a plurality of memory cells.

Data can be written, read and erased in each individual cell in an EEPROM memory. To write, read and erase only data in the memory cell M₁₁, the following voltages are applied to the above-mentioned lines:

| | CG₁ | SG₁ | BL₁ | CG_{2...j..} | SG_{2..j..} | BL_{2...i..} | SO |
|---|---|---|---|---|---|---|---|
| Writing | 0 V | +13 V | +11 V | 0 V | 0 V | 0 V | open |
| Erasing | +11 V | 0 V | 0 V | 0 V | 0 V | 0 V | open |
| Reading | +1 V | +3 V | +1 V | 0 V | 0 V | 0 V | 0 V |

During writing, the memory transistor T₂ receives a threshold voltage of about −3 V, and during erasing, this voltage will be about +3 V. When the data in memory cell ME₁₁ are being erased, the data in memory cells ME₂₁, ME₃₁ . . . MEᵢ₁ are erased simultaneously.

The FLASH-EPROM memory shown in FIG. 2 also comprises a matrix of memory cells MFᵢⱼ arranged in rows and columns, in which i is the number in the row and j is the number in the column. Each memory cells comprises a memory transistor T3 having a floating gate 4 and a control gate 5 and, arranged in series therewith, a transistor T4 having a control gate 6. The control gate 5 of a plurality of memory transistors T3, for example, eight or more transistors, are interconnected per column by lines CGⱼ, while the control gate 6 of the transistors T4 are interconnected per column by lines SGⱼ. The memory transistors T1 are also interconnected per row by bit lines BLᵢ, and the transistors T2 are also interconnected by a source line SO which is common for a plurality of memory cells. This circuit thus deviates at this point from that of the EEPROM memory.

To write, read and erase only data in the memory cell M₁₁ in this FLASH-EPROM memory, the following voltages are applied to the above-mentioned lines:

| | CG₁ | SG₁ | BL₁ | CG_{2...j..} | SG_{2...j..} | BL_{2...i..} | So |
|---|---|---|---|---|---|---|---|
| Writing | +13 V | 0 V | 0 V | 0 V | 0 V | +5 V | open |
| Erasing | −13 V | 0 V | 0 V | 0 V | 0 V | 0 V | open |
| Reading | +1.2 V | +3 V | +1 V | 1.2 V | 0 V | 0 V | 0 V |

During writing, the memory transistor T₃ receives a threshold voltage of about +3 V, and during erasing, this voltage will be about −3 V. Here again, the data in the memory cells MF₁₁, MF₂₁, . . . MFᵢ₁ are erased simultaneously.

When the memory cell MF₁₁ is being programmed, a high positive voltage of 13 V is applied to the control gate of the memory transistor T1 of this cell. This voltage is also applied to the control gate of the memory transistors of the memory cells MF₂₁, MF₃₁, . . . MFᵢ₁. To prevent these transistors from being programmed as well, a voltage of 5 V is applied to the bit lines BL₂, . . . , BLᵢ. This voltage of 5 V is also applied to the drain of all memory transistors which are connected to these bit lines. When this often happens and when there are program transistors among these transistors, the threshold voltage of these program transistors may change. Consequently, the stored data can be read in a less reliable way. This limits the number of times the memory cells can be programmed. This phenomenon does not occur in the EEPROM memory. Here, the memory transistors are connected to the common source line to which no voltage is applied during operation.

FIGS. 3 to 14 show diagrammatically and in cross-sections several stages of manufacturing the semiconductor device. The Figures show the manufacture of a memory cell ME of the EEPROM memory, the manufacture of a memory cell MF of the FLASH-EPROM memory and the manufacture of an n-type MOS transistor MOS which may be used in a circuit to be integrated beside the memories on the semiconductor body. It will be evident that, apart from these semiconductor elements, other elements such as p-type MOS transistors and MOS transistors suitable for switching at higher voltages can be manufactured in a simple manner when using the method described.

Active semiconductor regions 17, 18 and 19 are formed in a silicon body 10 at the area of the memory cells ME to be formed in the EEPROM memory and the memory cells MF to be formed in the FLASH-EPROM memory and the MOS transistor. As is shown in FIG. 1, the method starts from a customarily relatively heavily doped p-type silicon body 10 with an epitaxially grown, weaker doped p-type top layer 11 having a doping concentration of approximately 10¹⁵ atoms per cc. Field oxide regions 12 for the mutual insulation of the semiconductor regions 17, 18 and 19 to be formed are formed in the conventional manner on the silicon body, and the surface 13 is provided with a layer of silicon oxide 14. Subsequently, a photoresist mask 15 is formed on the layer of silicon oxide 14, leaving the layer 14 only free at the area of the memory cells ME to be formed. Customarily, the p-type semiconductor regions 17 are formed by implantation of ions, diagrammatically shown by means of broken line 16. Identically, the p-type semiconductor regions 18 are provided at the area of the memory cells MF to be formed and the p-type semiconductor regions 19 are provided at the area of the MOS transistor MOS to be formed.

To render the memory cells ME of the EEPROM memory more easily programmable, n-type tunnel zones 20 adjacent the surface 13 are formed in the semiconductor regions 17 at the area of the floating gate 1 to be formed in the memory transistors T1 to be formed in the memory cell ME of the EEPROM memory. The layer of silicon oxide 13 is subsequently removed. The silicon body 10 is now subjected to a treatment, herein further referred to as first oxidation treatment, in which the surface 13 is provided with a first layer of silicon oxide 21. The structure then formed is shown in FIG. 5.

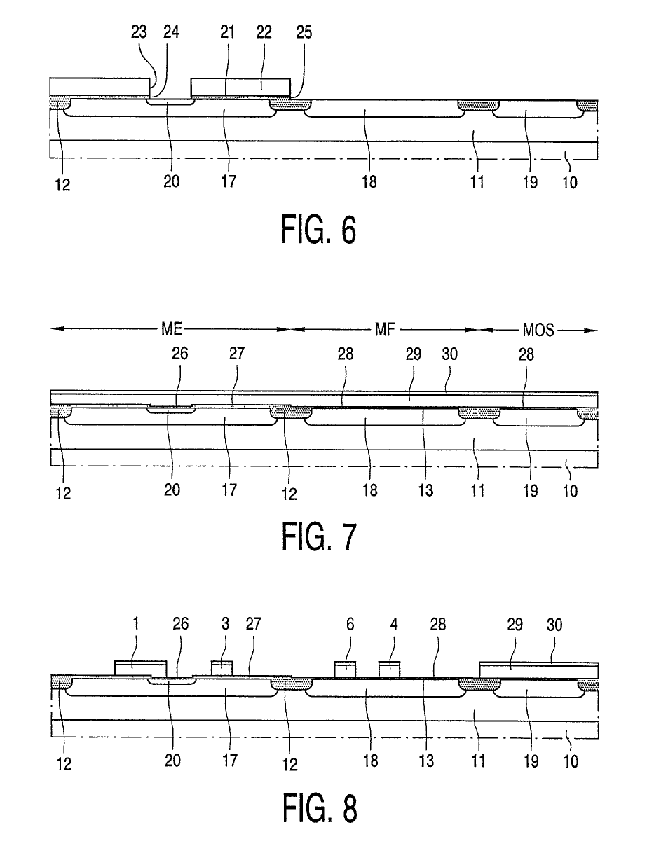

Subsequently a photoresist mask 22 is formed on this first layer of silicon oxide 21, which mask covers the semiconductor regions 17 at the areas where the memory cells ME are formed, and leaves free the semiconductor regions 18 and 19 where the memory cells MF and the MOS transistors MOS are formed. At the area of the tunnel zones 20, windows 23 are formed in the photoresist mask 22, within which windows the layer of silicon oxide 21 is also exposed. As is shown in FIG. 6, the uncovered part of the layer of silicon oxide is now etched away. Windows 24 are etched in the layer of silicon oxide 21 at the area of the tunnel zone 20, and windows 25 are etched in this layer at the area of the memory cells MJ and the MOS transistors MOS to be formed.

After the photoresist mask 23 has been removed, the silicon body 10 is subjected to a second oxidation process in which a second layer of silicon oxide 26 is formed within the windows 24 with a thickness of between 7 and 9 nm, which is such that this layer 26 may serve as a tunnel oxide for the memory transistors T1 to be formed in the EEPROM memory, and in which the first layer of silicon oxide 21 has such a larger thickness of between 15 and 25 nm that the thicker layer 27 thus formed can serve as a gate oxide for the selection transistors to be formed in the EEPROM memory. In this example, a layer of silicon oxide 27 is also formed during the second oxidation treatment on the surface 13 within the windows 25 at the area of the active semiconductor regions 18 and 19. This layer 27 then has a thickness of between 7 and 9 nm. The layer 27 may serve in this case as a tunnel oxide of the memory transistor T3 of the FLASH-EPROM memory and as a gate oxide of the transistor T4 arranged in series with the memory transistor T3. The tunnel oxide and the gate oxide required in the memory cells ME and MF of both memories is thus realized in a simple manner. In one process step, the windows 25 and 26 can be formed at the area of the floating gates 1 of the memory transistors T1 to be formed in the EEPROM memory and at the area of the memory cells MF of the FLASH-EPROM memory to be formed. Only two oxidation treatments are required.

After the two layers of silicon oxide 26 and 27, 28 have been formed, as shown in FIG. 7, a first approximately 250 nm thick n-type doped layer of polycrystalline silicon 29 having an approximately 10 nm thick top layer of silicon nitride 30 is formed on the surface 13. The floating gates 1 of the memory transistors T1 and the selection gates 3 of the selection transistors T2 of the memory cells ME of the EEPROM memory and the floating gates 4 of the memory transistors T3 and the control gates 6 of the transistors T4, arranged in series therewith, of the memory cells MF of the FLASH-EPROM memory are formed in these layers 29 and 30 in the conventional manner. The layers 29 and 30 on the active regions 19 are maintained for the MOS transistors. The formed gates 1, 3, 4 and 6 are provided on their sides with a thin layer of silicon oxide (not shown) by means of a short oxidation treatment.

Subsequently, relatively weakly doped n-type semiconductor zones 31 are formed by ion implantation in the conventional manner by using the masking effect of the gates 1, 3, 4 and 6, which semiconductor zones may serve as sources and drains for the transistors T1, T2, T3 and T4.

After the layer of silicon nitride 30 of the gates 1, 3, 4 and 6 and the polycrystalline silicon layer 29 on the active regions 19 have been removed, the gates 1, 3, 4 and 6 are provided with a dielectric 32, in this case a conventional layer of ONO (a layer of silicon oxide, covered with a layer of silicon nitride and a layer of silicon oxide). Subsequently, a second, approximately 250 nm thick layer of n-type polycrystalline silicon 33 is deposited on this layer 32. Subsequently, the control gates 2 of the memory transistors TI of the memory cells ME of the EEPROM memory and the control gates 5 of the memory transistors T3 of the memory cells MF of the FLASH-EPROM memory are formed in this polycrystalline silicon layer in the conventional manner.

While the control gates 2 and 5 are being used as a mask, the layer of ONO 32 is subsequently removed. Then, gate electrodes 33 for the MOS transistors MOS are formed in the first layer of polycrystalline silicon 29 which was still present on the active regions 19. While using the gate electrodes 33, n-type semiconductor zones 34, which may serve as sources and drains for the transistors MOS, are formed in the conventional manner.

The control gates 2 and 5, the selection gates 3 and 6 and the gate electrode 33 are customarily provided with spacers 35 of silicon oxide, whereafter higher doped contact zones 36 are formed in the n-type semiconductor zones 31 and 34. Subsequently, the assembly is covered with a layer of silicon oxide 37 in which contact windows 38 are formed for contacting the underlying semiconductor regions of the selection transistor T2 of the memory cell ME and the memory transistor T3 of the memory cell MF with bit lines BL.

In the semiconductor device described, the surface 13 is provided with a layer of silicon oxide 28 at the area of the memory cells MF of the FLASH-EPROM memory underneath the control gates 6 of the transistors T4 arranged in series with the memory transistors, which silicon oxide layer has a thickness which is equal to the thickness of the part having the smaller thickness 26 which is present underneath the floating gate 1 of the memory transistors T1 of the EEPROM memory. In the manufacture of this device, both the tunnel oxide 26 of the memory transistor T1 of the EEPROM memory and the gate oxide 28 of the transistor T4 arranged in series with the memory transistor T3 of the FLASH-EPROM memory can be formed with one layer of silicon oxide in one and the same process step. This layer is relatively thin. A gate oxide 28 having such a small thickness may be used because the above-mentioned special circuit is used in the semiconductor device. The layer of silicon oxide 28 is also used underneath the floating gates 4 of the memory transistors T3. Only two silicon oxide layers 27 and 26, 28 having a different thickness are required for manufacturing the EEPROM memory and the FLASH-EPROM memory.

1. A semiconductor device comprising an EEPROM and a FLASH-EPROM memory, in which the EEPROM memory comprises a matrix of rows and columns of memory cells with a selection transistor having a selection gate and, arranged in series therewith, a memory transistor having a floating gate and a control gate, in which the selection transistor is further connected to a bit line of the EEPROM memory and the memory transistor is connected to a source line of the EEPROM memory, which source line is common for a plurality of memory cells, and in which the FLASH-EPROM memory comprises a matrix of rows and columns of memory cells with a memory transistor having a floating gate and a control gate, characterized in that, in addition to the memory transistor having a floating gate and a control gate, the memory cells of the FLASH-EPROM memory comprise a transistor arranged in series with this memory transistor and having a control gate, the memory transistor being further connected to a bit line of the FLASH-EPROM memory, and the transistor arranged in series with the memory transistor being connected to a source line of the FLASH-EPROM memory, which source line is common for a large number of memory cells.

2. A semiconductor device as claimed in claim 1, comprising a silicon body having a surface which is provided at the area of the memory cells of the EEPROM memory with a layer of silicon oxide having a thickness which renders it suitable as a gate oxide for the selection transistor, which layer underneath the floating gate of the memory transistor is provided with a part having a smaller thickness which renders said part of the layer of silicon oxide suitable as a tunnel oxide for the memory transistor, characterized in that the surface of the silicon oxide is provided with a layer of silicon oxide at the area of the memory cells of the FLASH-EPROM memory underneath the control gates of the transistors arranged in series with the memory transistors, which layer of silicon oxide has a thickness which is equal to the thickness of the part having the smaller thickness and being present underneath the floating gate of the memory transistors of the EEPROM memory.

3. A semiconductor device as claimed in claim 2, characterized in that the surface of the silicon body is provided with a layer of silicon oxide at the area of the memory cells of the FLASH-EPROM memory underneath the floating gates of the memory transistors, which layer of silicon oxide has a thickness which is also equal to the thickness of the part having the smaller thickness and being present underneath the floating gate of the memory transistors of the EEPROM memory.

4. A method of manufacturing a semiconductor device as claimed in claim 3, characterized in that, after active semiconductor regions of a first conductivity type adjacent the surface of the silicon body have been formed in said silicon body at the area of the memory cells to be formed in the two memories, the silicon body is subjected to a first oxidation process in which the surface of the silicon body is provided with a first layer of silicon oxide in which windows are formed at the area of floating gates to be formed in the memory transistors of the EEPROM memory and at the area of the memory cells to be formed in the FLASH-EPROM memory, whereafter the silicon body is subjected to a second oxidation process in which a second layer of silicon oxide is formed within the windows with such a thickness that said layer can serve as a tunnel oxide for the memory transistors to be formed in both memories and as a gate oxide of the transistor arranged in series with the memory transistor of the FLASH-EPROM memory, and in which the first layer of silicon oxide acquires such a larger thickness that it can serve as a gate oxide for the selection transistors to be formed in the EEPROM memory.

5. A method of manufacturing a semiconductor device as claimed in claim 4, characterized in that, prior to the first oxidation treatment, the active regions for the memory cells of the EEPROM memory are provided with semiconductor zones of the first conductivity type adjacent the surface and serving as tunnel zones are formed at the area of the floating gates to be formed in the memory transistors, which semiconductor zones have a doping concentration which is higher than that of the active regions.

6. A method of manufacturing a semiconductor device as claimed in claim 4 or 5, characterized in that, after the formation of the two layers of silicon oxide, a first layer of amorphous or polycrystalline silicon is deposited in which the floating gates of the memory transistors and the selection gates of the selection transistors of the memory cells of the EEPROM memory, and the floating gates of the memory transistors and the control gates of the FLASH-EPROM memory transistors arranged in series therewith are formed.

7. A method of manufacturing a semiconductor device as claimed in claim 6, characterized in that, after the formation of the floating gates of the memory cells of both memories in the first layer of polycrystalline silicon, these floating gates are provided with a layer of dielectric, whereafter a second layer of amorphous or polycrystalline silicon is deposited, in which layer the control gates of the memory transistors of the memory cells of the EEPROM memory and the control gates of the memory transistors of the memory cells of the FLASH-EPROM memory are formed.
